(19) United States
(12) Patent Application Publication
(10) Pub. No.: US 2026/0189239 A1
(43) Pub. Date: Jul. 2, 2026

(54) PROCESSOR CHIP AND SERVER APPARATUS

(71) Applicant: Fujitsu Limited, Kawasaki-shi (JP)

(72) Inventors: Masanori DOI, Kawasaki (JP); Masanori HIGETA, Setagaya (JP); Takeo ASAKAWA, Kawasaki (JP)

(73) Assignee: Fujitsu Limited, Kawasaki-shi (JP)

(21) Appl. No.: 19/390,759

(22) Filed: Nov. 17, 2025

(30) Foreign Application Priority Data
Dec. 3, 2024 (JP) 2024-210745

(51) Int. Cl. H03L 7/183; H03L 7/085

(52) U.S. Cl. CPC H03L 7/183; H03L 7/085

(57) ABSTRACT

A processor chip having a plurality of processor cores, the processor chip including a phase-locked loop circuit configured to input a common oscillation value common to each of the plurality of processor cores, a first frequency change circuit configured to, in a first processor core of the plurality of processor cores, perform a given clock pulse skipping from the common oscillation value according to a first oscillation value set for the first processor core, and to operate the first processor core at the first oscillation value, and a second frequency change circuit configured to, in a second processor core of the plurality of processor cores, perform a given clock pulse skipping from the common oscillation value according to a second oscillation value set for the second processor core, and to operate the second processor core at the second oscillation value.

### CROSS-REFERENCE TO RELATED APPLICATION

This application is based upon and claims the benefit of priority of the prior Japanese Patent application No. 2024-210745, filed on Dec. 3, 2024, the entire contents of which are incorporated herein by reference.

### FIELD

The present disclosure relates to a processor chip and a server apparatus.

### BACKGROUND

In systems, such as High-Performance Computing (HPC) systems, the frequencies of the Central Processing Unit (CPU) cores may be changed during operation of the Operating System (OS) or firmware so as to meet certain requirements (for example, power limitations or faster computational speed).

In a multi-core processor, a plurality of CPU cores are provided in a CPU chip. A Phase Locked Loop (PLL) provided in the CPU chip may be used for changing the frequency of each CPU core.

For example, related arts are disclosed in Japanese Translation of PCT International Application No. 2011-501836.

### SUMMARY

According to an aspect of embodiment(s), a processor chip having a plurality of processor cores, the processor chip including a phase-locked loop circuit configured to input a common oscillation value common to each of the plurality of processor cores, a first frequency change circuit configured to, in a first processor core of the plurality of processor cores, perform a given clock pulse skipping from the common oscillation value according to a first oscillation value set for the first processor core, and to operate the first processor core at the first oscillation value, and a second frequency change circuit configured to, in a second processor core of the plurality of processor cores, perform a given clock pulse skipping from the common oscillation value according to a second oscillation value set for the second processor core, and to operate the second processor core at the second oscillation value.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram schematically illustrating an example of the configuration of a CPU chip in a first related example;

FIG. 2 is a block diagram schematically illustrating an example of the configuration of a CPU chip in a second related example;

FIG. 3 is a block diagram schematically illustrating an example of the configuration of a CPU chip in one example of an embodiment;

FIG. 4 is a circuit diagram schematically illustrating an example of the configuration of a frequency change circuit illustrated in FIG. 3;

FIG. 5 is a timing chart exemplifying clocks propagated to a CPU core illustrated in FIG. 3; and

FIG. 6 is a block diagram schematically illustrating an example of the hardware configuration of the server apparatus in an embodiment.

### DESCRIPTION OF EMBODIMENT(S)

When only a single PLL is provided in a CPU chip, it is impossible to operate each CPU core at a different frequency. Therefore, even a CPU core in an idle state without any job allocated from the OS or the like continues to operate at the same frequency as a CPU core processing a job, which may lead to increased power consumption.

On the other hand, when a plurality of PLLs associated with the respective CPU cores are provided in the CPU chip, it is possible to operate each CPU core at a different frequency. However, if the number of PLLs provided in the CPU chip is increased, the provision of the PLLs in the CPU chip may increase the circuit area.

### [A] Related Example

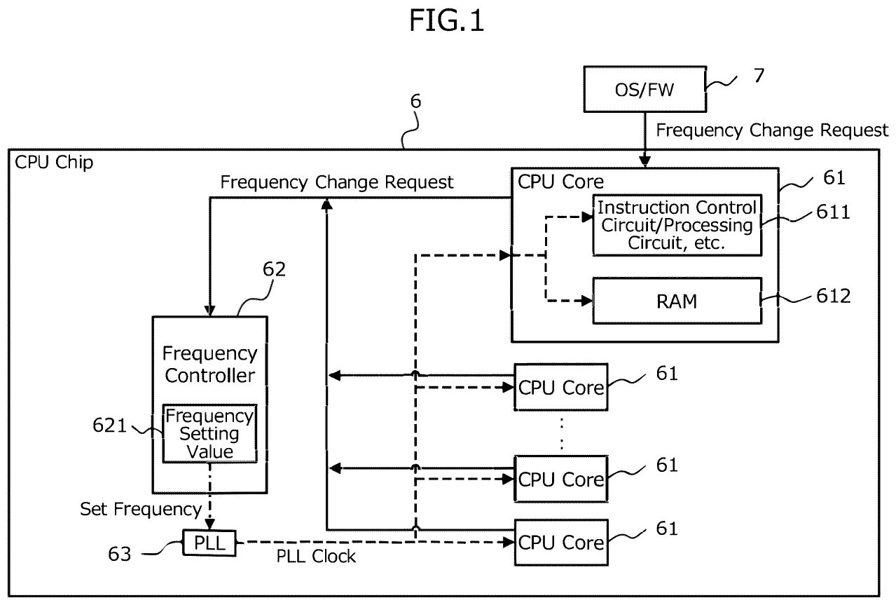

FIG. 1 is a block diagram schematically illustrating an example of the configuration of a CPU chip 6 in a first related example.

The CPU chip 6 illustrated in FIG. 1 may be configured with a single Large Scale Integration (LSI) chip, and includes a plurality of CPU cores 61, a frequency controller 62, and a PLL 63. Each of the plurality of CPU cores 61 includes an instruction control circuit/processing circuit, etc. 611 and a Random Access Memory (RAM) 612.

Each CPU core 61, in response to receiving an input of a frequency change request in accordance with the purpose of the operation of the CPU core 61 from the OS/Firmware (FW) 7 at the start of operation or the like, transfers the received frequency change request to the frequency controller 62.

The frequency controller 62 stores the frequency change request received from each CPU core 61 as a frequency setting value 621, and performs frequency setting for the PLL 63 in accordance with the frequency setting value 621. The frequency controller 62 sets, for the PLL 63, the largest frequency setting value 621 among the frequency setting values 621 corresponding to the respective CPU cores 61.

The PLL 63 operates each CPU core 61 with a PLL clock corresponding to the largest frequency setting value 621 set by the frequency controller 62.

As described above, when a only single PLL 63 is provided in the CPU chip 6, it is impossible to operate each CPU core 61 at a different frequency. Therefore, even a CPU core 61 in an idle state without any job allocated from the OS or the like continues to operate at the same frequency as a CPU core 61 processing a job, which may lead to increased power consumption.

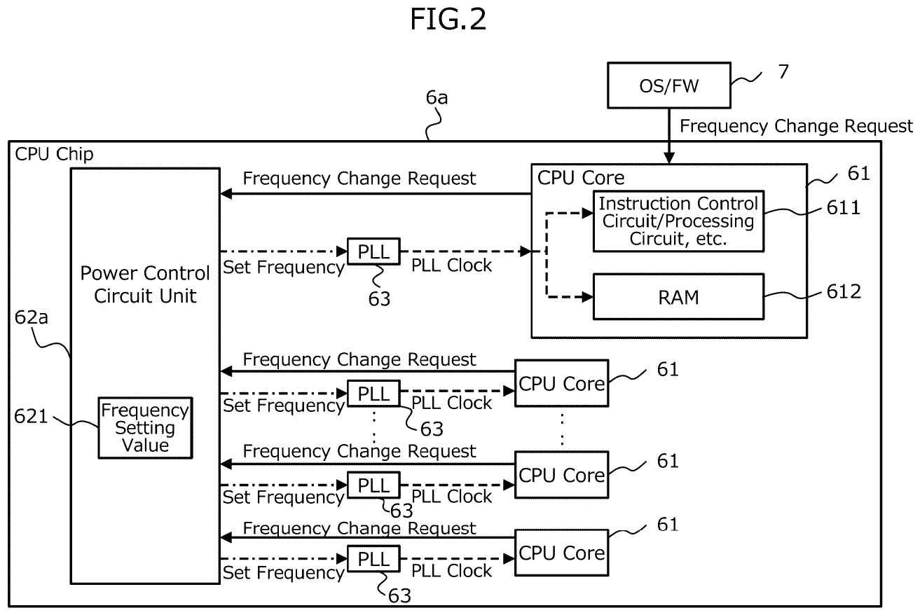

FIG. 2 is a block diagram schematically illustrating an example of the configuration of a CPU chip 6a in a second related example.

The CPU chip 6a illustrated in FIG. 2 may be configured with a single LSI chip, and includes a plurality of CPU cores 61, a power control circuit unit 62a, and a plurality of PLLs 63. Each of the plurality of CPU cores 61 includes an instruction control circuit/processing circuit, etc. 611 and a RAM 612.

Each CPU core 61, in response to receiving an input of a frequency change request in accordance with the purpose of the operation of the CPU core 61, from the OS/FW 7 at the start of operation or the like, transfers the received frequency change request to the power control circuit unit 62a.

The power control circuit unit 62a stores the frequency change request received from each CPU core 61 as a frequency setting value 621, and performs frequency setting for each PLL 63 in accordance with the frequency setting value 621. The frequency controller 62 sets, for each of the PLLs 63, different frequency setting values 621 corresponding to the respective CPU cores 61.

Each PLL 63 operates the associated CPU core 61 with a PLL clock corresponding to the frequency setting value 621 set by the frequency controller 62.

As described above, when a plurality of PLLs 63 corresponding to the respective CPU cores 61 are provided in the CPU chip 6a, it is possible to operate each CPU core 61 at a different frequency. However, if the number of PLLs 63 provided in the CPU chip 6s is increased, the provision of the PLLs 63 in the CPU chip 6a may increase the circuit area.

### [B] Embodiment

Hereinafter, one embodiment will be described with reference to the drawings. However, the embodiment described below is merely exemplary, and it is not intended to exclude various modifications or applications of techniques not explicitly described in the embodiment. In other words, the present embodiment may be embodied in various modifications without departing from the spirit thereof. In addition, each drawing does not imply that only the elements illustrated in the drawing are provided, but other functions or the like may also be included.

Hereinafter, in the drawings, the like reference symbols denote similar parts, and thus descriptions thereof are omitted.

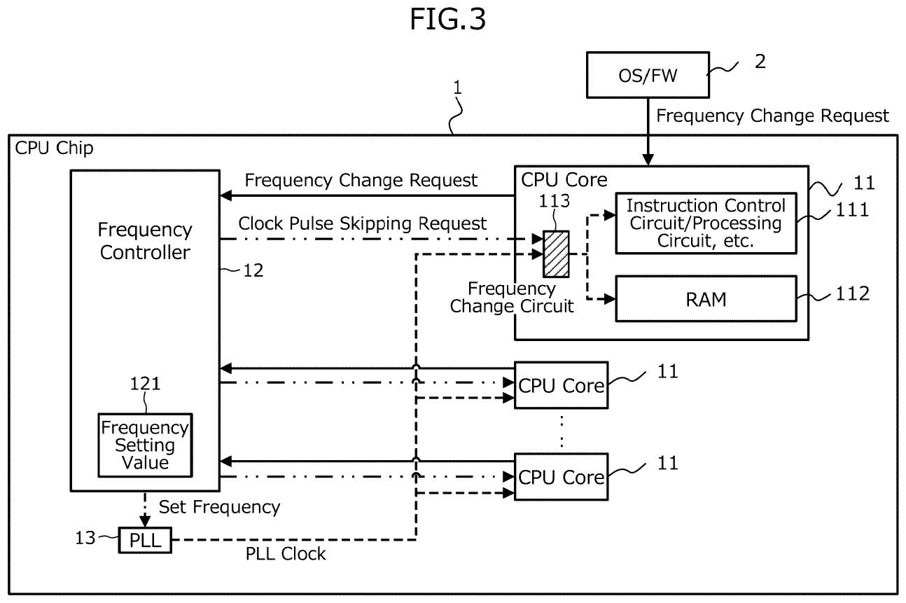

FIG. 3 is a block diagram schematically illustrating an example of the configuration of a CPU chip 1 in one example of an embodiment.

The CPU chip 1 illustrated in FIG. 3 is one example of a processor chip, may be configured with a single LSI chip, and includes a plurality of CPU cores 11, a frequency controller 12, and a single PLL 13. Each of the plurality of CPU cores 11 is one example of a processor core, and includes an instruction control circuit/processing circuit, etc. 111, a RAM 112, and a frequency change circuit 113.

Each CPU core 11, in response to receiving an input of a frequency change request in accordance with the purpose of the operation of the CPU core 11 from the OS/FW 2 at the start of operation or the like, transfers the received frequency change request to the frequency controller 12. The OS/FW 2 may also issue a frequency change request to the CPU core 11 at any time other than at the start of operation.

The frequency controller 12 stores the frequency change request received from each CPU core 11 as a frequency setting value 121, and performs frequency setting for the PLL 13 in accordance with the frequency setting value 121. The frequency controller 12 sets, for the PLL 13, the largest frequency setting value 121 among the frequency setting values 121 corresponding to the respective CPU cores 11.

The PLL 13, which is one example of a phase-locked loop circuit, operates each CPU core 11 with a PLL clock corresponding to the largest frequency setting value 121 set by the frequency controller 12.

In addition, the frequency controller 12 issues, in response to a frequency change request from each CPU core 11, a clock pulse skipping request to the each CPU core 11.

The frequency change circuit 113 of the CPU core 11 operates the instruction control circuit/processing circuit, etc. 111 and the RAM 112 using an oscillation value obtained by thinning out a given clock oscillation value from the PLL clock in response to a clock pulse skipping request from the frequency controller 12. The process of thinning out the given clock oscillation value from the PLL clock may be referred to as clock pulse skipping. It should be noted that clock pulse skipping is not executed for the CPU core 11 operating at the maximum frequency in the CPU chip 1, (in other words, the clock pulse skipping value is set to 0).

In other words, the PLL 13 inputs a common oscillation value common to each of the plurality of CPU cores 11. A first frequency change circuit 113 of the first CPU core 11 among the plurality of CPU cores 11 performs a given clock pulse skipping from the common oscillation value according to a first oscillation value set for the first CPU core 11, to operate the first CPU core 11 at the first oscillation value. A second frequency change circuit 113 of the second CPU core 11 among the plurality of CPU cores 11 performs a given clock pulse skipping from the common oscillation value according to a second oscillation value set for the second CPU core 11, to operate the second CPU core 11 at the second oscillation value.

Furthermore, when the second oscillation value is the largest among the plurality of oscillation values set for the respective CPU cores 11, and the first oscillation value is smaller than the second oscillation value, the PLL 13 inputs the second oscillation value as the common oscillation value. In this case, the first frequency change circuit 113 performs the given clock pulse skipping according to the ratio between the first oscillation value and the common oscillation value. In this case, the second frequency change circuit 113 performs the given clock pulse skipping with the clock pulse skipping value set to 0.

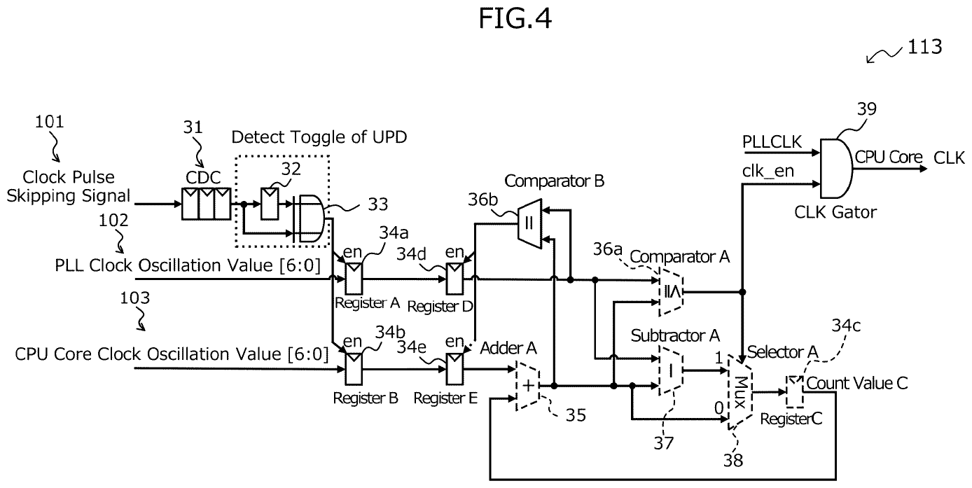

FIG. 4 is a circuit diagram schematically illustrating an example of the configuration of the frequency change circuit 113 illustrated in FIG. 3.

The frequency change circuit 113 illustrated in FIG. 4 includes a Clock Domain Crossing (CDC) 31, a register 32, an AND circuit 33, registers 34a to 34e, an adder 35, comparators 36a and 36b, a subtractor 37, a multiplexer (Mux) 38, and an AND circuit 39. The registers 34a to 34e may be respectively referred to as registers A to E, the adder 35 may be referred to as adder A, the comparators 36a and 36b may be respectively referred to as comparators A and B, and the subtractor 37 may be referred to as subtractor A. In addition, the Mux 38 may be referred to as selector A, and the AND circuit 39 may be referred to as CLK gater.

The frequency change circuit 113 in the CPU core 11 receives, from the frequency controller 12, a clock pulse skipping instruction signal 101, a PLL clock oscillation value 102 indicating the oscillation frequency of the PLL clock, and a CPU core clock oscillation value 103 for setting the CPU core clock.

The frequency change circuit 113 may be provided with a synchronization circuit for the clock pulse skipping instruction signal 101, so that when the clock of the CPU core 11 is not synchronized with the PLL clock, the CDC 31 synchronizes the PLL clock and the clock of the CPU core 11.

Thereafter, the register 32 and the AND circuit 33 detect the rising edge of the clock pulse skipping signal (in other words, detect the toggle of an update signal (UPD)), which serves as a write enable signal for the registers 34a (A) and 34b (B).

When writing is enabled, the PLL clock oscillation value 102 and the CPU core clock oscillation value 103 input to the frequency change circuit 113 are respectively written into and held in the registers 34a (A) and 34b (B).

The frequency change circuit 113 includes a comparator 36a (A) that compares a count value C, which is the sum of the CPU core clock oscillation value 103 and the value held in the register 34c (C), with the PLL clock oscillation value 102. The comparator 36a (A) outputs 1 if the count value C is greater than a given value, and outputs 0 if the count value C is less than the given value.

The register 34c (C), through the Mux 38 (Selector A), takes in the CPU core clock oscillation value 103 input to the comparator 36a (A) when the CPU core clock oscillation value 103 is smaller than a given value. The count value C of the register 34c (C) is added to the CPU core clock oscillation value 103 by the adder 35 (A) and set into the register C.

At this time, when the comparator 36a (A) determines that the count value C is greater than or equal to the PLL clock oscillation value 102, 1 is output, and the value E obtained by subtracting the PLL clock oscillation value 102 from the count value C by the subtractor 37 (A) is set into the register C from the Mux 38 (Selector A).

At this time, the output signal of the comparator 36a (A) is connected to the AND circuit 39 (CLK gater) as clk_en (clock enable). When clk_en=1, PLLCLK (PLL clock) is oscillated from the frequency change circuit 113 and propagates inside the CPU core 11.

The registers 34a (A) and 34b (B) can be updated each time when the rising edge of the clock pulse skipping signal is detected. However, the processing of the frequency change circuit 113 is performed when the comparator 36b (B) determines that the PLL clock oscillation value 102 and the count value C are equal, in which case the output from the comparator 36b (B) is taken into the registers 34d (D) and 34e (E) to start the process for skipping the clock. These registers 34d (D) and 34e (E) may be implemented to prevent unintended frequencies from being oscillated.

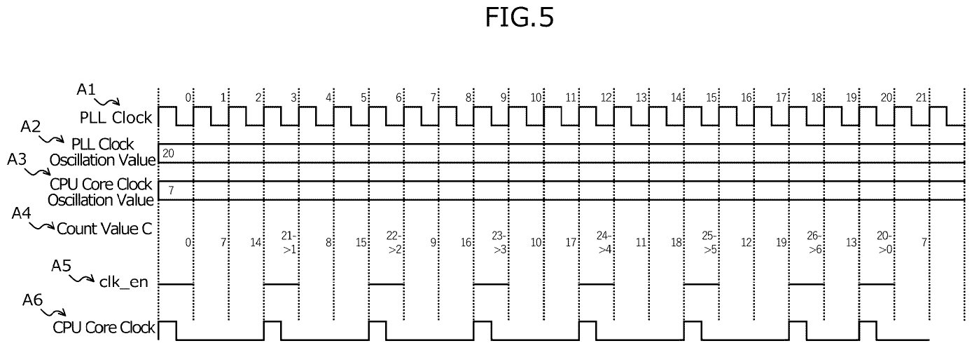

FIG. 5 is a timing chart exemplifying clocks propagating to the CPU core 11 illustrated in FIG. 3.

In FIG. 5, the PLL clock (see reference symbol A1), the PLL clock oscillation value (see reference symbol A2), the CPU core clock oscillation value (see reference symbol A3), the count value C (see reference symbol A4), clk_en (see reference symbol A5), and the CPU core clock (see reference symbol A6) are illustrated.

In the example illustrated in FIG. 5, the PLL clock oscillation value is set to 20 and the CPU core clock oscillation value is set to 7.

At period 0 of the PLL clock, the count value C is 0, clk_en is input and the CPU core clock rises.

At period 1 of the PLL clock, a CPU core clock oscillation value of 7 is added to the count value C, so that the count value C becomes 7, and at period 2 of the PLL clock, a CPU core clock oscillation value of 7 is added to the count value C, so that the count value C becomes 14.

At period 3 of the PLL clock, a CPU core clock oscillation value of 7 is added to the count value C, so that the count value C becomes 21. Since the count value C becomes greater than or equal to the PLL clock oscillation value, which is 20, clk_en is input and the CPU core clock rises. At this time, the PLL clock oscillation value of 20 is subtracted from the count value C of 21, updating the count value C to 1.

At period 4 of the PLL clock, a CPU core clock oscillation value of 7 is added to the count value C, so that the count value C becomes 8, and at period 5 of the PLL clock, a CPU core clock oscillation value of 7 is added to the count value C, so that the count value C becomes 15.

At period 6 of the PLL clock, a CPU core clock oscillation value of 7 is added to the count value C, so that the count value C becomes 22. Since the count value C becomes greater than or equal to the PLL clock oscillation value, which is 20, clk_en is input and the CPU core clock rises. At this time, the PLL clock oscillation value of 20 is subtracted from the count value C of 22, updating the count value C to 2.

Thereafter, the same CPU core clock rising repeatedly occurs. Although a timing chart for one CPU core 11 (for example, the first CPU core 11) is illustrated in FIG. 5, this timing chart also applies to other CPU cores 11 (for example, the second CPU core 11).

In other words, the first frequency change circuit 113 holds a first count value C, and for each one period of a common clock corresponding to the common oscillation value input by the PLL 13, adds the first oscillation value to the first count value. The first frequency change circuit 113 raises the clock to operate the first CPU core 11 at the timing when the first count value becomes greater than or equal to the common oscillation value. The second frequency change circuit 113 holds a second count value C, and for each one period of a common clock corresponding to the common oscillation value input by the PLL 13, adds the second oscillation value to the second count value C. The second frequency change circuit 113 raises a clock for operating the second CPU core 11 at a timing when the second count value becomes equal to or greater than the common oscillation value.

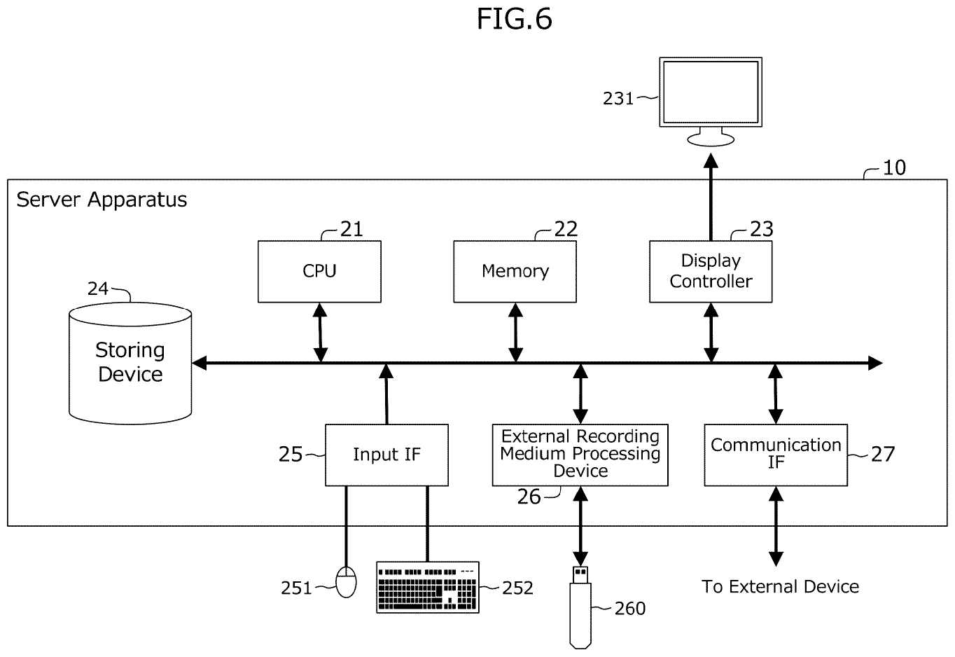

FIG. 6 is a block diagram schematically illustrating an example of the hardware configuration of a server apparatus 10 in an embodiment.

As illustrated in FIG. 10, the server apparatus 10 includes a CPU 21, a memory 22, a display controller 23, a storing device 24, an input interface (IF) 25, an external recording medium processing device 26, and a communication IF 27.

The memory 22 is one example of a storage unit and may include, as an example, a Read Only Memory (ROM) and a RAM. Programs such as a Basic Input/Output System (BIOS) may be written in the ROM of the memory 22. Software programs in the memory 22 may be loaded into and executed by the CPU 21 as appropriate. In addition, the RAM of the memory 22 may be used as a temporary storage memory or a working memory.

The display controller 23 is connected to a display device 231 and controls the display device 231. The display device 231 may be a liquid crystal display, an Organic Light-Emitting Diode (OLED) display, a Cathode Ray Tube (CRT), an electronic paper display, or the like, and displays various information to the operator or other uses of the server apparatus 10. The display device 231 may be integrated with an input device, and may be, for example, a touch panel.

As the storing device 24, a Solid State Drive (SSD), a Storage Class Memory (SCM), or a Hard Disk Drive (HDD) may be used.

The input IF 25 is connected to input devices such as a mouse 251 and a keyboard 252, and may control the input devices such as the mouse 251 and the keyboard 252. The mouse 251 and the keyboard 252 are examples of input devices, and various input operations may be performed by the operator of the arithmetic processing apparatus 2 through these input devices.

The external recording medium processing device 26 is configured to allow the mounting of a recording medium 260. The external recording medium processing device 26 is configured to allow reading of information recorded on the recording medium 260 while the recording medium 260 is mounted. In this example, the recording medium 260 is portable. For example, the recording medium 260 may be a non-temporary recording medium such as a flexible disk, an optical disk, a magnetic disk, a magneto-optical disk, or a semiconductor memory.

The communication IF 27 is an interface for enabling communication with an external device.

The CPU 21 corresponds to the CPU chip 1 illustrated in FIG. 3. The CPU 21 is one example of a processor and is a processing device that performs various controls and arithmetic operations. The CPU 21 embodies various functions by executing an OS or programs loaded into the memory 22. It should be noted that the CPU 21 may be a multiprocessor including a plurality of CPUs or a multicore processor having a plurality of CPU cores 11, or is configured to have a plurality of multicore processors.

The device that controls the operation of the entire server apparatus 10 is not limited to the CPU 21 and may be any one of an MPU, a DSP, an ASIC, a PLD, and an FPGA. Alternatively, the device that controls the operation of the entire server apparatus 10 may be a combination of two or more of a CPU, an MPU, a DSP, an ASIC, a PLD, and an FPGA. It should be noted that MPU is an abbreviation for Micro Processing Unit, DSP is an abbreviation for Digital Signal Processor, and ASIC is an abbreviation for Application Specific Integrated Circuit. In addition, PLD is an abbreviation for Programmable Logic Device, and FPGA is an abbreviation for Field Programmable Gate Array.

### [C] Effects

The PLL 13 inputs a common oscillation value common to each of the plurality of CPU cores 11. The first frequency change circuit 113 of the first CPU core 11 among the plurality of CPU cores 11 performs the given clock pulse skipping of the common oscillation value according to the first oscillation value set for the first CPU core 11, to operate the first CPU core 11 at the first oscillation value. The second frequency change circuit 113 of the second CPU core 11 among the plurality of CPU cores 11 performs the given clock pulse skipping of the common oscillation value according to the second oscillation value set for the second CPU core 11, to operate the second CPU core 11 at the second oscillation value.

As a result, it becomes possible to control the power consumption in accordance with the operating state of each CPU core 11 in a multicore processor.

Specifically, it is possible to skip the clocks by the frequency change circuits 113 of the CPU cores 11 to change the frequency of each CPU core 11, without increasing the number of PLLs 13 in the LSI. Then, by changing the frequency for each CPU core 11, it becomes possible to control the power consumption in accordance with the operating state of the CPU cores 11, such as suppressing power consumption of CPU cores 11 in an idle state. Also, since the frequency change circuit 113 can be configured with a smaller circuit scale than the PLL 13, the number of circuits is reduced compared to cases where there are a plurality of PLLs 13, which can suppress the impact on cost.

When the second oscillation value is the largest among the plurality of oscillation values set for each of the plurality of CPU cores 11, and the first oscillation value is smaller than the second oscillation value, the PLL 13 inputs the second oscillation value as the common oscillation value. In this case, the first frequency change circuit 113 performs the given clock pulse skipping according to the ratio between the first oscillation value and the common oscillation value. In this case, the second frequency change circuit 113 performs the given clock pulse skipping with the clock pulse skipping value set to 0.

As a result, the switching whether or not clock pulse skipping according to the CPU core clock set for each CPU core 11 is executed or not is selected.

The first frequency change circuit 113 holds a first count value, and adds the first oscillation value to the first count value for each one period of a common clock corresponding to the common oscillation value input by the PLL 13. The first frequency change circuit 113 raises the clock to operate the first CPU core 11 at the timing when the first count value becomes greater than or equal to the common oscillation value. The second frequency change circuit 113 holds a second count value, and adds a second oscillation value to the second count value for each one period of a common clock corresponding to the common oscillation value input by the PLL 13. The second frequency change circuit 113 raises a clock for operating the second CPU core 11 at a timing when the second count value becomes equal to or greater than the common oscillation value.

As a result, clock pulse skipping can be accurately performed.

### [D] Others

The disclosed technique is not limited to the above-described embodiment, and various modifications may be embodied without departing from the spirit of the present embodiment. Each element and each processing of the present embodiment may be selected as needed, or may be combined as appropriate.

In one aspect, the power consumption can be controlled in accordance with the operating state of each CPU core in a multi-core processor.

Throughout the descriptions, the indefinite article “a” or “an” does not exclude a plurality.

All examples and conditional language recited herein are intended for the pedagogical purposes of aiding the reader in understanding the invention and the concepts contributed by the inventor to further the art, and are not to be construed limitations to such specifically recited examples and conditions, nor does the organization of such examples in the specification relate to a showing of the superiority and inferiority of the invention. Although one or more embodiments of the present inventions have been described in detail, it should be understood that the various changes, substitutions, and alterations could be made hereto without departing from the spirit and scope of the invention.

What is claimed is:

1. A processor chip having a plurality of processor cores, the processor chip comprising:
a phase-locked loop circuit configured to input a common oscillation value common to each of the plurality of processor cores;
a first frequency change circuit configured to, in a first processor core of the plurality of processor cores, perform a given clock pulse skipping from the common oscillation value according to a first oscillation value set for the first processor core, and to operate the first processor core at the first oscillation value; and
a second frequency change circuit configured to, in a second processor core of the plurality of processor cores, perform a given clock pulse skipping from the common oscillation value according to a second oscillation value set for the second processor core, and to operate the second processor core at the second oscillation value.

2. The processor chip according to claim 1,
wherein, when the second oscillation value is the largest among a plurality of oscillation values set for the respective plurality of processor cores, and the first oscillation value is smaller than the second oscillation value,
the phase-locked loop circuit is configured to input the second oscillation value as the common oscillation value,
the first frequency change circuit is configured to perform the given clock pulse skipping according to a ratio between the first oscillation value and the common oscillation value, and
the second frequency change circuit is configured to perform the given clock pulse skipping with the clock pulse skipping value set to 0.

3. The processor chip according to claim 1,
wherein the first frequency change circuit is configure to hold a first count value, add the first oscillation value to the first count value for each one period of a common clock corresponding to the common oscillation value input by the phase-locked loop circuit, and raise a clock to operate the first processor core at the timing when the first count value becomes greater than or equal to the common oscillation value, and
the second frequency change circuit is configure to hold a second count value, add the second oscillation value to the second count value for each one period of the common clock, and raise a clock to operate the second processor core at the timing when the second count value becomes greater than or equal to the common oscillation value.

4. The processor chip according to claim 2,
wherein the first frequency change circuit is configure to hold a first count value, add the first oscillation value to the first count value for each one period of a common clock corresponding to the common oscillation value input by the phase-locked loop circuit, and raise a clock to operate the first processor core at the timing when the first count value becomes greater than or equal to the common oscillation value, and
the second frequency change circuit is configure to hold a second count value, add the second oscillation value to the second count value for each one period of the common clock, and raise a clock to operate the second processor core at the timing when the second count value becomes greater than or equal to the common oscillation value.

5. A server apparatus comprising a processor chip having a plurality of processor cores,
the processor chip comprising:
a phase-locked loop circuit configured to input a common oscillation value common to each of the plurality of processor cores;
a first frequency change circuit configured to, in a first processor core of the plurality of processor cores, perform a given clock pulse skipping from the common oscillation value according to a first oscillation value set for the first processor core, and to operate the first processor core at the first oscillation value; and
a second frequency change circuit configured to, in a second processor core of the plurality of processor cores, perform a given clock pulse skipping from the common oscillation value according to a second oscillation value set for the second processor core, and to operate the second processor core at the second oscillation value.

6. The server apparatus according to claim 5,
wherein, when the second oscillation value is the largest among a plurality of oscillation values set for the respective plurality of processor cores, and the first oscillation value is smaller than the second oscillation value,
the phase-locked loop circuit is configured to input the second oscillation value as the common oscillation value,
the first frequency change circuit is configured to perform the given clock pulse skipping according to a ratio between the first oscillation value and the common oscillation value, and
the second frequency change circuit is configured to perform the given clock pulse skipping with the clock pulse skipping value set to 0.

7. The server apparatus according to claim 5,
wherein the first frequency change circuit is configure to hold a first count value, add the first oscillation value to the first count value for each one period of a common clock corresponding to the common oscillation value input by the phase-locked loop circuit, and raise a clock to operate the first processor core at the timing when the first count value becomes greater than or equal to the common oscillation value, and
the second frequency change circuit is configure to hold a second count value, add the second oscillation value to the second count value for each one period of the common clock, and raise a clock to operate the second processor core at the timing when the second count value becomes greater than or equal to the common oscillation value.

8. The server apparatus according to claim 6,
wherein the first frequency change circuit is configure to hold a first count value, add the first oscillation value to the first count value for each one period of a common clock corresponding to the common oscillation value input by the phase-locked loop circuit, and raise a clock to operate the first processor core at the timing when the first count value becomes greater than or equal to the common oscillation value, and
the second frequency change circuit is configure to hold a second count value, add the second oscillation value to the second count value for each one period of the common clock, and raise a clock to operate the second processor core at the timing when the second count value becomes greater than or equal to the common oscillation value.
